(19) United States
(12) Patent Application Publication
(10) Pub. No.: US 2026/0323978 A1
(43) Pub. Date: Oct. 15, 2026

(54) GAN HETEROSTRUCTURE DEVICES AND METHODS OF MAKING

(71) Applicant: Analog Device, Inc., Wilmington, MA (US)

(72) Inventor: Mohamed Azize, Medford, MA (US)

(21) Appl. No.: 19/423,457

(22) Filed: Dec. 17, 2025

Related U.S. Application Data
(60) Provisional application No. 63/735,241, filed on Dec. 17, 2024.

(51) Int. Cl. H10D 30/47; H10D 30/01

(52) U.S. Cl. CPC H10D 30/4732; H10D 30/015

(57) ABSTRACT

A compound semiconductor integrated circuit can include a high electron mobility transistor (HEMT). A body region can include GaN formed upon a substrate. The HEMT can include a source region; a drain region; a gate region; a gate-source access region and a gate-drain access region; an aluminum gallium nitride (AlGaN) layer on the body region; an alloy layer on the AlGaN layer. The alloy layer can include AlₓSc₁₋ₓN or AlₓIn₁₋ₓN. An aluminum nitride (AlN) layer can be formed upon the alloy layer in at least one of the gate-drain or the gate source access regions of an enhancement mode HEMT device on the IC with electrons from the AlN layer contributing to a 2DEG in a channel region. One or more of the layers can be formed by low temperature chemical vapor deposition (CVD) at a first temperature of less than 400 degrees Celsius together with concurrent physical vapor deposition (PVD) at the same first temperature.

### CLAIM OF PRIORITY

This patent application claims the benefit of priority of U.S. Provisional Patent Application No. 63/735,241 entitled GAN HETEROSTRUCTURE DEVICES AND METHODS OF MAKING, filed Dec. 17, 2024 (Attorney Docket No. 3867.C93PRV), which is hereby incorporated herein by reference in its entirety.

### TECHNICAL FIELD

This document pertains generally, but not by way of limitation, to semiconductor devices and manufacturing, and more particularly, but not by way of limitation to techniques for forming materials such as AlₓSc₁₋ₓN or AlₓIn₁₋ₓN for GaN heterostructure structures and devices.

### BACKGROUND

Compound semiconductors can provide advantages over silicon in forming integrated circuit devices. Some compound semiconductors allow for optical or photonic applications, and some compound semiconductors provide wide bandgaps that can be useful in high-voltage or high power applications, such as for power transistors and radio-frequency (RF) communication applications. However, processing compound semiconductors can be more expensive and more complicated than processing silicon.

### SUMMARY/OVERVIEW

One problem in compound semiconductor devices can arise from a desire to reduce expense by forming the compound semiconductor on a less expensive substrate, such as a silicon substrate. For example, gallium nitride (GaN) is a useful compound semiconductor, which can be grown or otherwise formed upon a less expensive silicon substrate, but a lattice mismatch between the GaN the silicon can cause defects in the GaN that can degrade device operation of field-effect transistors (FETs) or other GaN devices. The FETs can employ bilayer or other heterostructures, such as a GaN layer upon which an aluminum gallium nitride (AlGaN) layer can be formed, such as to create a two dimensional electron gas (“2DEG”) conductive layer region located between two insulating layers. While the resulting structure can be a depletion-mode (normally on) FET, it is also possible and desirable to provide a resulting structure that be an enhancement mode (EMODE, normally off) FET device.

For example, a portion of the region between the source and drain terminals of the FET can be selectively etched to remove the 2DEG gas over that selectively-etched portion, and when it is desired that the FET be turned on, the FET gate terminal can be biased positively to inject electrons from the FET gate region to form the 2DEG gas in that selectively-etched portion.

Another approach is to selectively form a p-type GaN gate region under the gate terminal to create a PN junction with the underlying AlGaN material, such as to form a depletion region under the selectively-formed p-type GaN gate region. The depletion region will be depleted of electrons and will be normally off, thereby providing an enhancement mode FET device. By biasing the gate terminal positively, an electron channel region can be created using the selectively-formed p-type GaN gate region, such that a continuous channel can be formed between the source and drain of the GaN FET device to provide an enhancement mode “on” state of the FET. Providing the p-type GaN region for forming an enhancement mode device, however, will impact the drain-to-source sheet resistance. Because the channel region may not provide enough electrons to form a 2DEG electron gas, the higher channel region “on”-resistance (Ron) may impede the efficiency of the FET device, such as in a power transistor application.

The present inventor has recognized, among other things, the problem posed by such a higher Ron. Accordingly, the present approach can include techniques, such as can include both methods of manufacture and resulting structures, to provide a GaN heterostructure for a high electron mobility FET or other transistor (HEMT) with reduced Ron and, in turn, higher efficiency. The present approach can, in an illustrative example, help lower Ron for an EMODE GaN HEMT, such as by a factor of between 5 and 10, which can be very helpful for high voltage power transistor applications, such as which can range between 12 Volts and 1200 Volts. Briefly, this document describes, among other things, a compound semiconductor integrated circuit can include a high electron mobility transistor (HEMT). A body region can include GaN formed upon a substrate. The HEMT can include a source region; a drain region; a gate region; a gate-source access region and a gate-drain access region; an aluminum gallium nitride (AlGaN) layer on the body region; an alloy layer on the AlGaN layer. The alloy layer can include AlₓSc₁₋ₓN or AlₓIn₁₋ₓN. An aluminum nitride (AlN) layer can be formed upon the alloy layer in at least one of the gate-drain and gate-source access regions of an enhancement mode HEMT device on the IC with electrons from the AlN layer contributing to a 2DEG in a channel region. One or more of the layers can be formed by low temperature chemical vapor deposition (CVD), such as at a first temperature of less than 400 degrees Celsius, together with concurrent physical vapor deposition (PVD) at the same first temperature.

This Summary/Overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIGS. 1A, 1B illustrate an example of a comparative approach of forming a depletion-mode GaN FET (FIG. 1A) and an enhancement mode GaN FET (FIG. 1B).

FIG. 1C is a conceptual example of a graph of a figure of merit (FOM) vs. a drain voltage rating for evolving GaN technology.

FIG. 2A (3D perspective view), 2B (cross-section of vertically-stacked multi-channels), and 2C (top Scanning Electron Micrograph (SEM) view of the nanostructured gate region) show an example of a comparative approach in a of a multi-channel tri-gate HEMT device, such as in which the multi-channels can be formed using MOCVD to be multiple stacked layers that can be stacked in a vertical direction above the underlying substrate and any intervening layers.

FIG. 3A shows a comparative approach for comparison with Example 1 of the present approach shown in FIG. 3B.

FIGS. 4A, 4B are similar to FIGS. 3A, 3B, respectively, but in FIG. 4B an Example 2 is shown in which the low temperature CVD with PVD process can be used to selectively grow, in the HEMT access regions, a single channel stack of 1-25 nanometer thick AlN upon 1-25 nanometer thick AlₓSc₁₋ₓN, which stack can be repeated vertically upward if multi-channels are desired for even higher performance

FIG. 5 shows a graph of lattice constant parameter, a, in Angstroms, vs. percentage of Scandium composition for various compositions of AlₓSc₁₋ₓN.

### DETAILED DESCRIPTION

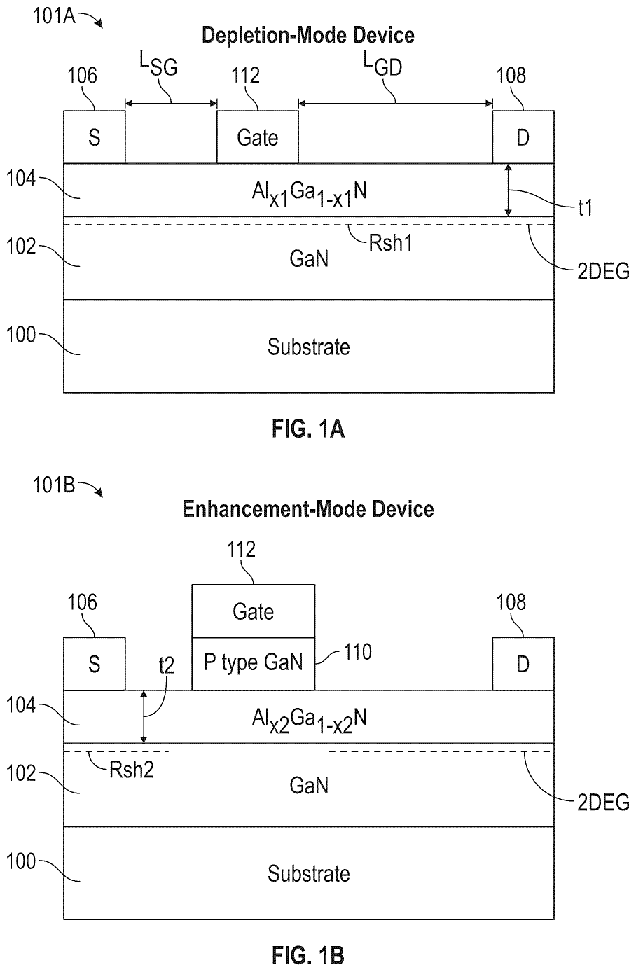

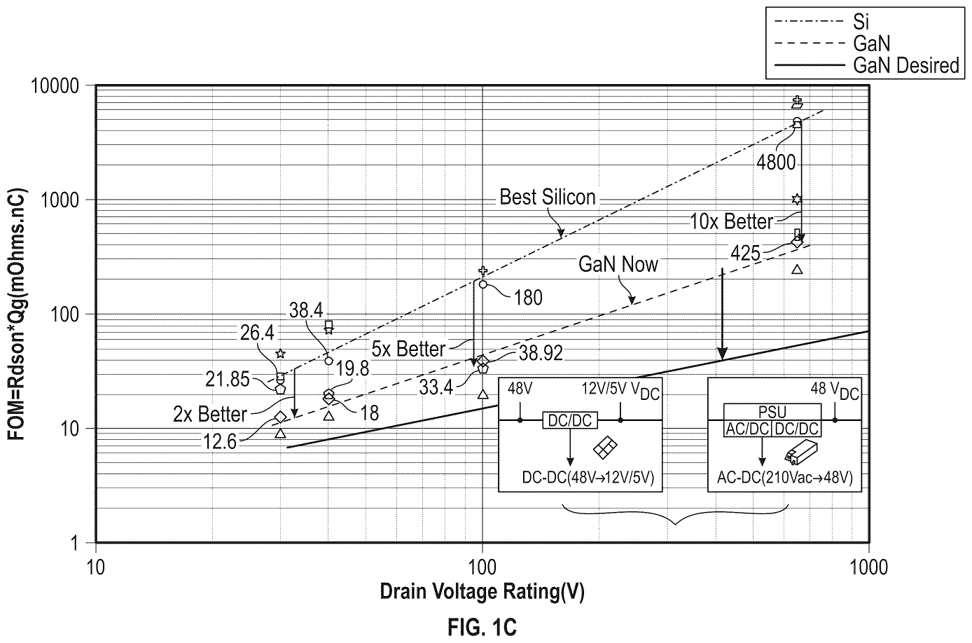

FIGS. 1A, 1B illustrate an example of a comparative approach of forming a depletion-mode GaN FET device 101A (FIG. 1A) and an enhancement mode GaN FET device 101B (FIG. 1B). Both FIGS. 1A-1B can start with a silicon or other semiconductor or other substrate 100 upon which a GaN layer 102 can be formed. Upon the GaN layer 102, an AlGaN layer 104 can be formed, such as which can be selectively formed with a thickness t2 and a higher aluminum content (Alₓ₂Ga₁₋ₓ₂N) for the enhancement mode device 101B in FIG. 1B than for the thickness t1 and its corresponding aluminum content of the depletion mode device 101A (Alₓ₁Ga₁₋ₓIN) of FIG. 1A. A FET source 106 terminal and a FET drain 108 terminal can be formed on the AlGaN layer 104. A p-type GaN region 110 can be selectively formed between the drain 108 and the source 106 for the enhancement mode device 101B of FIG. 1B, but omitted from the depletion mode device 101A of FIG. 1A. A gate 112 terminal can be formed upon the p-type GaN region for the enhancement mode device 101B of FIG. 1B, and directly upon the AlGaN layer 104 for the depletion mode device 101A of FIG. 1A. The thickness of the AlGaN layer 104 and its aluminum percentage content (X %) can be limited, such as for the enhancement mode device 101B of FIG. 1B, such as to be able to deplete the 2DEG electron gas by the p-type GaN gate region 110. This creates a technical challenge in that the emode GaN device 101B with the p-type GaN region 110 will have a thinner underlying thickness t2 of its AlGaN region 104 than the corresponding thickness t1 of the AlGaN layer 104 in the depletion mode device 101A, and the aluminum content of the AlGaN layer 104 of depletion mode device 101A will be greater than the aluminum content of the AlGaN layer 104 of the enhancement mode device 101B, such that the drain-to-source sheet resistance Rsh2 (and corresponding Ron) of the enhancement mode device 101B will be greater than the drain-to-source sheet resistance Rsh1 of the depletion mode device 101A. In use, this higher Ron can cause energy losses, particularly at high power, which reduces the efficiency of the enhancement mode device 101B. The present approach, however, can help reduce the sheet resistance Rs of the access regions (corresponding to source-gate length LsG and gate-drain length LGD), including in the enhancement mode device 101B, such as explained herein. Thus, the present approach can allow full operation for both the depletion mode device 101A and the enhancement mode device 101B on the same integrated circuit (IC), including at drain voltage operating levels between 12 Volts and 1200 Volts, which is helpful for the evolution of GaN technology such as shown in FIG. 1C, which is a graph of a figure of merit (FOM) on the y-axis vs. drain voltage rating on the x-axis, where the FOM is the product of the drain-to-source “on” resistance (RDSON) in milliohms and the gate charge in nanocoulombs.

Technical challenges to be overcome are now further described. Forming GaN by epitaxial grown in a metal-organic chemical vapor deposition (MOCVD) chamber is extremely challenging due to the lattice and thermal mismatch (e.g., between GaN and an underlying silicon or other substrate). There can be considerable total tensile stress, such as during the epitaxy and the subsequent cooling down step (e.g., from 1000 degrees Celsius to room temperature). In certain approaches, a GaN HEMT has not yet reached its highest potential performance, such as can be illustrated by the FOM of FIG. 1C. For instance, in certain approaches, the Ronsp ranges from 10-20 milliohm*millimeter² (such as for low voltage applications at a drain-source voltage of less than 200V) to 800-1000 milliohm*millimeter² (such as for high voltage applications between 650 Volts and 1200 Volts). One effective way to enhance GaN HEMT device performance can include increasing its carrier concentration (Nₛ) in the channel region, which directly results in a smaller on-resistance (R_{ON}). Yet, increasing Nₛ can lead to major challenges for the heterostructure and device design and manufacturing. A larger Nₛ can severely impact the carrier mobility (μ), thereby limiting the reduction of the heterostructure sheet resistance (Rₛₕ). A larger carrier concentration can also result in a difficult gate control of the channel region, which can hinder enhancement-mode operation and, in the “off” state, can degrade the device blocking voltage performance.

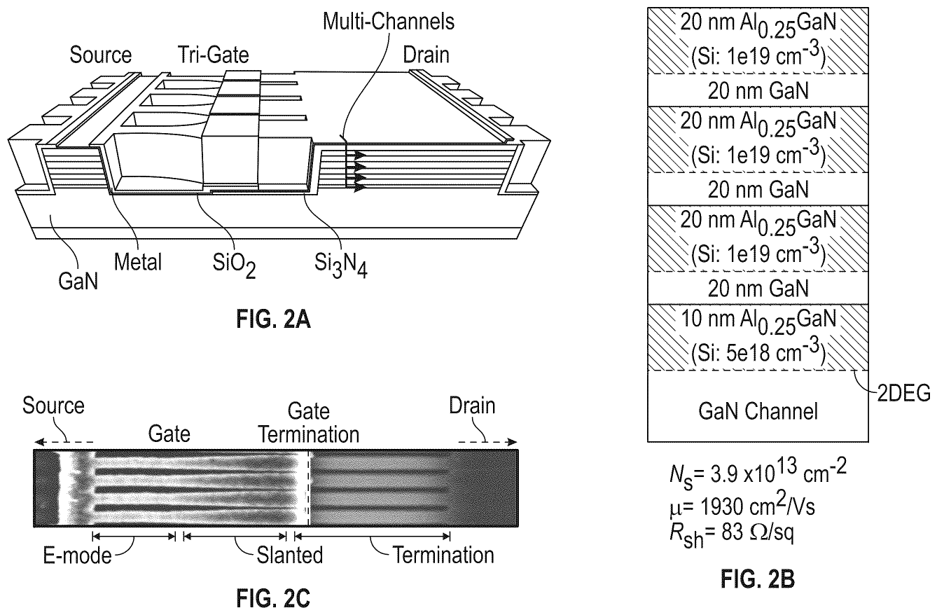

FIG. 2A (3D perspective view), 2B (cross-section of vertically-stacked multi-channels), and 2C (top Scanning Electron Micrograph (SEM) view of the nanostructured gate region) show an example of a comparative approach of a multi-channel tri-gate HEMT device, such as in which the multi-channels can be formed using MOCVD to be multiple stacked layers that can be stacked in a vertical direction above the underlying substrate and any intervening layers. In the example of FIGS. 2A-2C, the above-mentioned trade-off of increasing Ns can be addressed using multi-channel heterostructures, such as in which several barrier/-and-channel layer pairs can be vertically stacked to achieve multiple vertically-arranged 2DEGs therebetween, which allow increasing the Ns and thus the heterostructure conductivity.

In FIGS. 2A, 2B, and 2C, the Ronsp can be about 0.46 milliOhms centimeter², with Rsh being about 96 ohms/square, and the carrier mobility being about 1930cm²/V·s, with Ns being about 3.9·1013/cm², with Ron being about 3.4 ohm·mm.

However, the comparative approach of FIGS. 2A, 2B, and 2C may also present some drawbacks. First, it can be complex to be reproduce at scale, in terms of epitaxy quality, since the vertically-arranged stacking of the multi-layers using MOCVD may lead to cracking. Second, it can be complex in that it may need a post processing (etching) step, and such etching will need to stop accurately on the active channel. Third, a large tensile stress can be generated during the MOCVD epitaxy (e.g., at 1000 degrees C.) and the subsequent cooling down to room temperature. This tensile stress may not always be reproducible, and the epitaxy processing step may be hard to perform for a thick buffer, leaving practical use limited to using a thin buffer. Fourth, the multi-channel approach may impact gate region stress, which is why nanoribbons and a tri-gate arrangement may be needed to relax the strain in the resulting structure. Fifth, the multiple channels may introduce parasitic capacitances, which can be undesirable at high frequency operation.

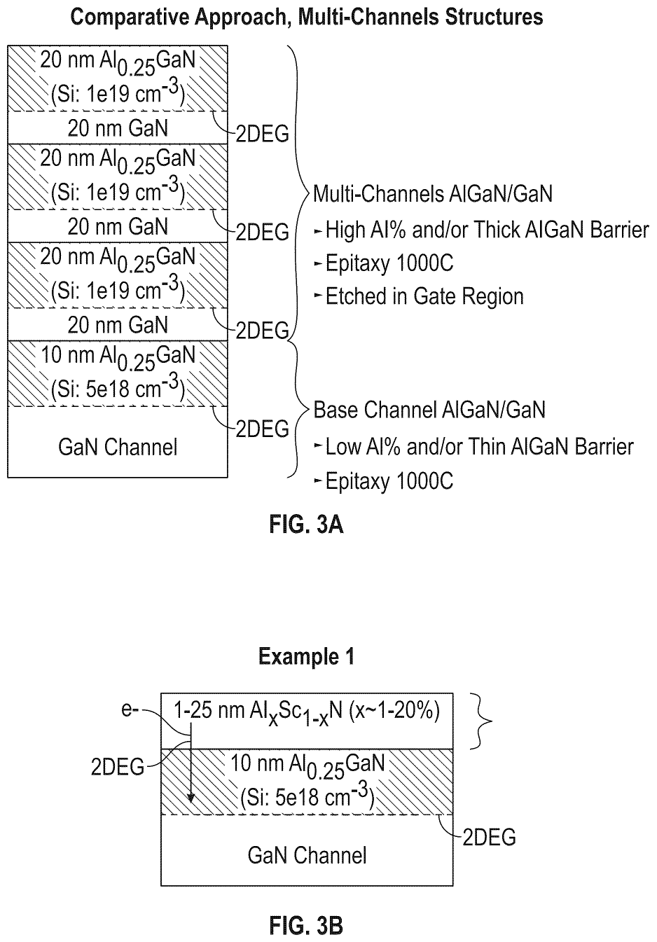

FIGS. 3A, 3B are side cross-sectional views, with FIG. 3A showing a multi-channel comparative approach for comparison with Example 1 of the present approach, which is shown in FIG. 3B. As explained above, the comparative approach of FIG. 3A can include vertically stacking multiple bi-layers of GaN and AlGaN for forming multiple channels, such as shown in FIGS. 2A, 2B, and 2C. At the bottom of the stack of FIG. 3A, the base channel bi-layer of AlGaN and GaN layers can include a low aluminum content percentage, a thick AlGaN barrier, or both, and can be performed using MOCVD to perform epitaxy at 1000 degrees C. Similarly, subsequent bi-layers of GaN and AlGaN can be formed to add to the vertical stack and provide multiple vertically stacked channels, with these additional bi-layers to the base bi-layer including a higher aluminum content percentage, a thicker AlGaN barrier layer, or both, again using MOCVD epitaxy at 1000 degrees C., and involving etching in the gate region, such as explained above, for performing such selective growth. In the comparative high temperature (e.g., 1000 degrees Celsius) MOCVD example of FIG. 3A, the resulting vertical stack of AlGaN on GaN bi-layers (4 bi-layers of AlGaN on GaN layers), can provide the resulting Ns=3.9×10¹³ electrons/cm², providing a carrier mobility of 1930 cm²/Vs and a sheet resistance of Rsh=83 Ω/square.

With this comparative approach of FIG. 3A in mind, FIG. 3B shows Example 1 of the present approach, in which an Aluminum Scandium Nitride layer (e.g., AlₓSc₁₋ₓN) can be selectively regrown onto the HEMT's access regions (e.g., between Source and Gate regions (defining L_{SG}) and between the Gate and Drain regions (defining L_{GD}) such as shown in FIGS. 1A, 1B, such as using low-temperature (e.g., <400 degrees C.) Chemical Vapor Deposition (CVD) with Physical Vapor Deposition (PVD) processes (e.g., sputtering). This can employ a low temperature CVD with a PVD chamber having vertically-oriented wafers during the epitaxial growth, such as available from Element 3-5 GmbH (Baseweiller, Germany). Such low temperature CVD with PVD using vertically oriented wafers can perform the epitaxial growth at much lower temperatures than an MOCVD chamber, in which the wafers are horizontally arranged for performing the high temperature (e.g., 1000 degree Celsius) MOCVD epitaxial growth. Using the approach of Example 1, such as can employ low temperature CVD with PVD using vertically-oriented wafers, more than 1 order of magnitude more electrons can be injected via the resulting single channel formed by AlScN layer upon the base AlGaN/GaN bi-layer, such as shown in FIG. 3B, than by using the four bi-layers forming vertically-stacked channels shown in the comparative approach of FIG. 3A. For example, a single channel approach such as shown in FIG. 3B can provide the resulting Ns=10¹⁴ electrons/cm², providing a carrier mobility of 1000-2000 cm²/Vs and a sheet resistance of Rsh<100 Ω/square.

Thus, using the approach shown in FIG. 3B, the single channel employed can deliver better performance than the multiple channels employed using the comparative approach of FIG. 3A. Moreover, the approach of Example 1 shown in FIG. 3B can be extended to a multi-channel approach, using multiple vertically stacked arrangements of AlScN/AlGaN/GaN, if even higher performance is desired, but this is optional and not required. Due to the higher piezo coefficient and larger bandgap of AlScN than AlGaN, a 2DEG electron gas can be generated when AlScN is deposited upon AlGaN or, optionally, upon AlN/AlGaN. Moreover, as mentioned above, multi-channels (e.g., more than a single layer of AlScN deposited on AlGaN or upon AlN/AlGaN can optionally be repeated to keep further reducing the sheet resistance in the access regions defining LSG & LGD, such as if further improved performance is desired, however, this is not required. A 2DEG electron gas can also be created between AlN/AlScN, due to the difference of the piezo coefficient between AlN and AlScN as well as the larger bandgap of AlN as compared to AlScN. Thus, the approach described in Example 1 and depicted in FIG. 3B permits formation of novel single-or multi-channels AlN/AlₓSc₁₋ₓN that can be lattice-matched to AlₓGa₁₋ₓN layers, which, in combination with the Low temperature (e.g., <400 degrees C.) CVD with PVD process employed, can help limit the stress introduced into the adjacent gate region to a minimal stress.

Therefore, the CVD with PVD deposition post-growth on access regions of enhancement mode HEMT devices will not impact the threshold voltage (Vth), and the normally-off operation of the enhancement mode device can be conserved with a reduced sheet resistance (Rsh) provided in the access regions of the resulting HEMT structure.

Further, multi-layers of AlN/AlₓSc₁₋ₓN can be employed to generate tensile stress into the access regions of the HEMT. This will induce more electrons into AlGaN/GaN access regions' heterostructures while depleting the electrons from the AlGaN/GaN gate regions due to the compressive stress that can be induced. Thus, the threshold voltage, Vth, can be shifted toward higher positive values than would be the case for the comparative approach and its resulting threshold voltage, Vth.

This high threshold voltage enhancement mode HEMT can be highly desirable in GaN-based commercial power electronics since for most comparative approaches the threshold voltage is limited to 1V≤Vth≤2V for GaN HEMT FETs, as compared to a Si power FET that can provide a threshold voltage of between 2-4V for low voltage Si FET and between 4-6V for medium and high voltage Si FET, which Example 1 of the present approach can help achieve.

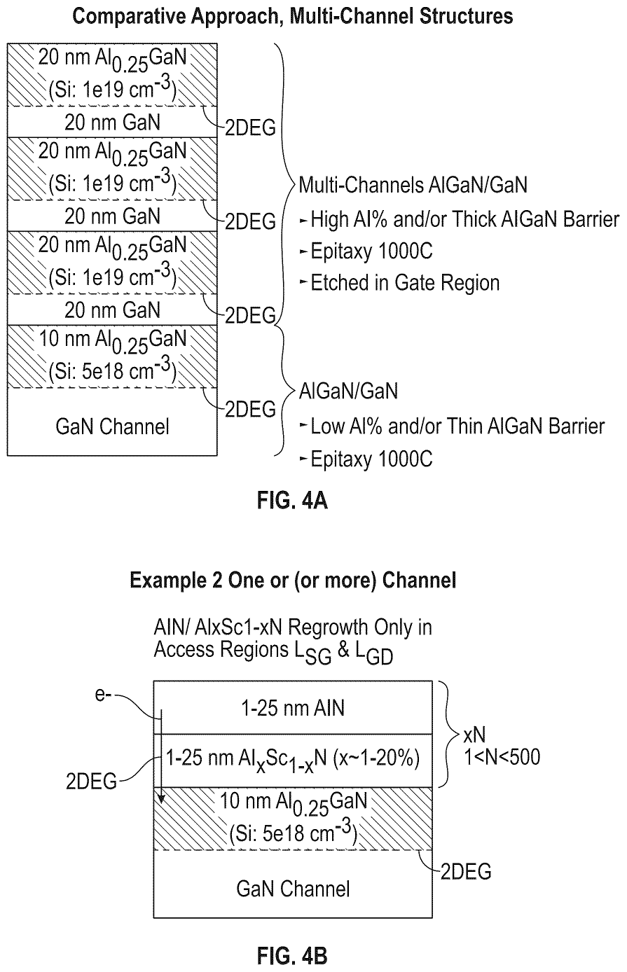

FIGS. 4A, 4B are similar to FIGS. 3A, 3B, respectively, but in FIG. 4B an Example 2 is shown in which the low temperature CVD with PVD process can be used to selectively grow, in the HEMT access regions, a single channel stack of 1 to 25 nanometer thick AlN upon 1 to 25 nanometer thick AlₓSc₁₋ₓN (e.g., with the value of x being between 1% and 20%), which stack can be repeated vertically upward (e.g., N times, with the value of N being between 1 and 500) if multi-channels are desired for even higher performance.

In the comparative high temperature (e.g., 1000 degrees Celsius) MOCVD example of FIG. 4A, the resulting vertical stack of AlGaN on GaN bi-layers (4 bi-layers of AlGaN on GaN layers), can provide the resulting Ns=3.9×10¹³ electrons/cm², providing a carrier mobility of 1930 cm²/Vs and a sheet resistance of Rsh=83 Ω/square.

By contrast, in a single channel approach such as shown in FIG. 4B can provide the resulting Ns=10¹⁴ electrons/cm², providing a carrier mobility of 1000-2000 cm²/Vs and a sheet resistance of Rsh<100 Ω/square, which can be improved even further if the stack of bi-layers is repeated.

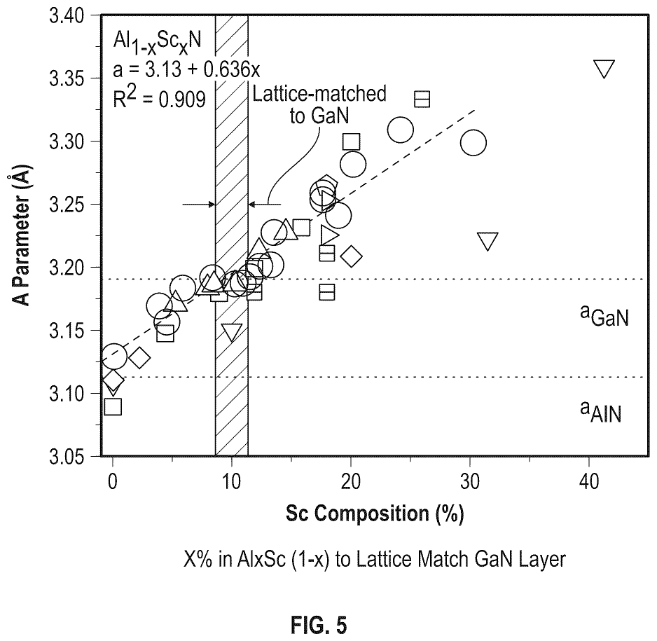

FIG. 5 shows a graph of lattice constant parameter, a, in Angstroms, VS. percentage of Scandium composition for various compositions of AlₓSc₁₋ₓN. The lattice constant of GaN is a_{GaN}=3.189 angstroms, the lattice constant of AlN is a_{AlN}=3.112 angstroms, and the lattice constant of ScN is a_{ScN}=4.50 angstroms. Using linear interpolation for the alloy AlₓSc₁₋ₓN, the lattice constant of the alloy is a_{AlxSc1-xN}=X*a_{AlN}+(1−x)a_{ScN}. Setting the lattice match condition a_{AlxSc1-xN}=a_{GaN} and x*a_{AlN}+(1−x) a_{ScN}=a_{GaN}, and solving for x, yields x=a_{GaN}-a-_{ScN}/a_{AlN}-a_{ScN}, or x=0.945. Thus, in theory the percentage composition of Sc is x~5.5%, and empirically is between 8 percent and 12%, or possibly even up to 20%. In sum, it is possible to lattice match AlₓSc₁₋ₓN to GaN fairly well, which can be advantageous, such as to reduce stress or strain between such layers.

To recap, it is possible to achieve piezo-doping of the top layer of AlₓSc₁₋ₓN into an AlGaN/GaN system, such as can be used to selectively form enhancement mode and depletion mode HEMT devices suitable for high power transistor applications as well as for co-integrated low voltage circuitry, if desired. Using AlₓSc₁₋ₓN instead of or in addition to AlGaN, the main channel 2DEG electron gas density can be increased, such as via piezo-doping of AlN/AlScN systems for a single channel or for vertically stacked multi-channel devices. Using a single channel arrangement, less parasitic capacitance will be present as compared to a multi-channel approach, which can help provide improved high frequency performance of a high power HEMT transistor.

To recap and further describe, a numbered list of Aspects/Examples is listed below.

Aspect 1 can include or use a method of making (and a resulting device or article of manufacture) a compound semiconductor high electron mobility transistor (HEMT). The HEMT can include a body region and can further include a source region, a drain region, and a gate region that define a gate-source access region and a gate-drain access region. The method of making can include forming a gallium nitride (GaN) body region layer deposition upon a silicon or other substrate. The method of making can also include forming an aluminum gallium nitride (AlGaN) buffer layer by deposition upon the GaN body region layer. The method of making can also include forming an aluminum scandium nitride (AlₓSc₁₋ₓN) alloy layer on the AlGaN layer by low temperature chemical vapor deposition (CVD) at a first temperature of less than 400 degrees Celsius together with concurrent physical vapor deposition (PVD) at the same first temperature. The method of making can also include using the low temperature CVD with the concurrent PVD, forming an aluminum nitride (AlN) layer upon the AlₓSc₁₋ₓN alloy layer in at least the gate-drain access region of an enhancement mode HEMT device such that electrons from the AlN layer contribute to a 2DEG in a channel region of GaN body region of at least one of the gate-drain access region or the gate-drain access region.

Aspect 2 can include or use, or can be combined with one or more features of Aspect 1 to include or use a method of making inn which the forming the AlₓSc₁₋ₓN alloy layer can include selectively forming the gate-source access region and the gate-drain access region separately to provide different compositions of the AlₓSc₁₋ₓN alloy layer.

Aspect 3 can include or use, or can be combined with one or more features of any of Aspects 1 or 2 to include or use a method of making in which the forming the AlₓSc₁₋ₓN alloy layer includes selectively forming depletion mode HEMT devices and enhancement mode HEMT devices having different compositions of the AlₓSc₁₋ₓN alloy layer and co-integrated on the same integrated circuit die.

Aspect 4 can include or use, or can be combined with one or more features of any of Aspects 1 through 3 to include or use repeating the forming the AlGaN layer, the forming the AlₓSc₁₋ₓN alloy layer, and the forming the AlN layer, to form a vertically-stacked multi-channel HEMT device.

Aspect 5 can include or use, or can be combined with one or more features of any of Aspects 1 through 4 to include or use forming the AlGaN buffer layer by deposition includes forming the AlGaN buffer layer by the low temperature CVD with concurrent PVD.

Aspect 6 can include or use, or can be combined with one or more features of any of Aspects 1 through 5 to include or use forming the GaN body region layer by deposition such that it can include forming the GaN body region layer by the low temperature CVD with concurrent PVD.

Aspect 7 can include or use, or can be combined with one or more features of any of Aspects 1 through 6 to include or use the low temperature CVD with concurrent PVD to include sputtering.

Aspect 8 can include or use, or can be combined with one or more features of any of Aspects 1 through 7, in which the low temperature CVD with concurrent PVD is performed in a chamber in which wafers are not arranged horizontally.

Aspect 9 can include or use, or can be combined with one or more features of any of Aspects 1 through 8, in which the low temperature CVD with concurrent PVD is performed in a chamber in which wafers are arranged vertically.

Aspect 10 can include or use, or can be combined with one or more features of any of Aspects 1 through 9, in which the AlₓSc₁₋ₓN alloy layer is formed with x less than 20%.

Aspect 11 can include or use, or can be combined with one or more features of any of Aspects 1 through 10, in which the AlₓSc₁₋ₓN alloy layer is formed with x between 5.5% and 12%.

Aspect 12 can include or use, or can be combined with one or more features of any of Aspects 1 through 11, to include or use a compound semiconductor integrated circuit including a high electron mobility transistor (HEMT). The integrated circuit can include the HEMT having a body region that includes GaN and that is formed upon a substrate, a source region, a drain region, a gate region, a gate-source access region, and a gate-drain access region. The IC can include or use an aluminum gallium nitride (AlGaN) layer on the body region. The IC can include or use an aluminum scandium nitride (AlₓSc₁₋ₓN) alloy layer on the AlGaN. The IC can include or use an aluminum nitride (AlN) layer upon the AlₓSc₁₋ₓN alloy layer in at least the gate-drain access region of an enhancement mode HEMT device on the integrated circuit arranged such that electrons from the AlN layer contribute to a 2DEG in a channel region of body region of at least one of the gate-drain access region and the gate-source access region.

Aspect 13 can include or use, or can be combined with one or more features of any of Aspects 1 through 12, to include or use the AlₓSc₁₋ₓN alloy layer to include different compositions of the AlₓSc₁₋ₓN alloy layer in the gate-source access region and the gate-drain access region.

Aspect 14 can include or use, or can be combined with one or more features of any of Aspects 1 through 13, to include or use a depletion mode HEMT and an enhancement mode HEMT co-integrated on the same integrated circuit die but having different compositions of the AlₓSc₁₋ₓN alloy layer therebetween.

Aspect 15 can include or use, or can be combined with one or more features of any of Aspects 1 through 14, to include or use repeating the AlGaN layer, the AlₓSc₁₋ₓN alloy layer, and the AlN layer to form a vertically-stacked multi-channel HEMT device.

Aspect 16 can include or use, or can be combined with one or more features of any of Aspects 1 through 15, to include or use at least one of the AlGaN layer, the AlₓSc₁₋ₓN alloy layer, and the AlN layer including a sputtered layer.

Aspect 17 can include or use, or can be combined with one or more features of any of Aspects 1 through 16, to include or use the AlₓSc₁₋ₓN alloy layer to include a composition having x less than 20%.

Aspect 18 can include or use, or can be combined with one or more features of any of Aspects 1 through 17, to include or use the AlₓSc₁₋ₓN alloy layer including a composition having x between 5.5% and 12%.

Aspect 19 can include or use, or can be combined with one or more features of any of Aspects 1 through 18, to include or use a method of making a compound semiconductor high electron mobility transistor (HEMT) (or the resulting integrated circuit or HEMT), with the HEMT including a body region and further including a source region, a drain region, a gate region that define a gate-source access region and a gate-drain access region. The method of making can also include forming a gallium nitride (GaN) body region layer deposition upon a silicon or other substrate. The method of making can also include forming an aluminum gallium nitride (AlGaN) buffer layer by deposition upon the GaN body region layer. The method of making can also include forming an alloy layer including at least one of: (1) an aluminum scandium nitride (AlₓSc₁₋ₓN) alloy layer, or (2) an aluminum indium nitride (AlₓIn₁₋ₓN) alloy layer, the alloy layer formed on the AlGaN layer by low temperature chemical vapor deposition (CVD) at a first temperature of less than 400 degrees Celsius together with concurrent physical vapor deposition (PVD) at the same first temperature. The method of making can also include using the low temperature CVD with the concurrent PVD, forming an aluminum nitride (AlN) layer upon alloy layer in at least the gate-drain access region of an enhancement mode HEMT device such that electrons from the AlN layer contribute to a 2DEG in a channel region of GaN body region of gate-drain access region.

Aspect 20 can include or use, or can be combined with one or more features of any of Aspects 1 through 19, to include or use forming an alloy layer including at least one of: (1) an aluminum scandium nitride (AlₓSc₁₋ₓN) alloy layer, or (2) an aluminum indium nitride (AlₓIn₁₋ₓN) alloy layer, includes forming the aluminum scandium nitride (AlₓSc₁₋ₓN) alloy layer.

Aspect 21 can include or use, or can be combined with one or more features of any of Aspects 1 through 20, to include or use forming an alloy layer including at least one of: (1) an aluminum scandium nitride (AlₓSc₁₋ₓN) alloy layer, or (2) an aluminum indium nitride (AlₓIn₁₋ₓN) alloy layer, includes forming the aluminum indium nitride (AlₓIn₁₋ₓN) alloy layer.

Aspect 22 can include or use, or can be combined with one or more features of any of Aspects 1 through 21, to include or use a compound semiconductor integrated circuit including a high electron mobility transistor (HEMT). The HEMT on the integrated circuit can include a body region that includes GaN and that is formed upon a substrate, a source region, a drain region, a gate region, a gate-source access region. and a gate-drain access region. The IC can include an aluminum gallium nitride (AlGaN) layer on the body region. The IC can include an alloy layer on the AlGaN layer, the alloy layer including at least one of: (1) an aluminum scandium nitride (AlₓSc₁₋ₓN) alloy layer on the AlGaN, or (2) an aluminum indium nitride (AlₓIn₁₋ₓN) alloy layer on the AlGaN. The IC can include an aluminum nitride (AlN) layer upon the alloy layer in at least the gate-drain access region of an enhancement mode HEMT device on the integrated circuit arranged such that electrons from the AlN layer contribute to a 2DEG in a channel region of body region of gate-drain access region.

Aspect 23 can include or use, or can be combined with one or more features of any of Aspects 1 through 22, to include or use the alloy layer to include the aluminum scandium nitride (AlₓSc₁₋ₓN) alloy layer.

Aspect 24 can include or use, or can be combined with one or more features of any of Aspects 1 through 23, to include or use the alloy layer to include the aluminum indium nitride (AlₓIn₁₋ₓN) alloy layer.

The above description includes references to the accompanying drawings, which form a part of the detailed description. The drawings show, by way of illustration, specific embodiments in which the invention can be practiced. These embodiments are also referred to herein as “aspects” or “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following aspects, the terms “including” and “comprising” are open-ended, that is, a system, device, article, composition, formulation, or process that includes elements in addition to those listed after such a term in a aspect are still deemed to fall within the scope of that aspect. Moreover, in the following aspects, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the aspects. Also, in the above Detailed Description, various features may be grouped together to streamline the disclosure. This should not be interpreted as intending that an unclaimed disclosed feature is essential to any aspect. Rather, inventive subject matter may lie in less than all features of a particular disclosed embodiment. Thus, the following aspects are hereby incorporated into the Detailed Description as examples or embodiments, with each aspect standing on its own as a separate embodiment, and it is contemplated that such embodiments can be combined with each other in various combinations or permutations. The scope of the invention should be determined with reference to the appended aspects, along with the full scope of equivalents to which such aspects are entitled.

The claimed invention is:

1. A method of making a compound semiconductor high electron mobility transistor (HEMT), including a body region and further including a source region, a drain region, a gate region that define a gate-source access region and a gate-drain access region, the method comprising:
forming a gallium nitride (GaN) body region layer deposition upon a silicon or other substrate;
forming an aluminum gallium nitride (AlGaN) buffer layer by deposition upon the GaN body region layer;
forming an aluminum scandium nitride (AlₓSc₁₋ₓN) alloy layer on the AlGaN layer by low temperature chemical vapor deposition (CVD) at a first temperature of less than 400 degrees Celsius together with concurrent physical vapor deposition (PVD) at the same first temperature; and
using the low temperature CVD with the concurrent PVD, forming an aluminum nitride (AlN) layer upon the AlₓSc₁₋ₓN alloy layer in at least the gate-drain access region of an enhancement mode HEMT device such that electrons from the AlN layer contribute to a 2DEG in a channel region of GaN body region of at least one of a gate-drain access region or a gate-source access region.

2. The method of claim 1, in which the forming the AlₓSc₁₋ₓN alloy layer includes selectively forming the gate-source access region and the gate-drain access region separately to provide different compositions of the AlₓSc₁₋ₓN alloy layer.

3. The method of claim 1, in which the forming the AlₓSc₁₋ₓN alloy layer includes selectively forming depletion mode HEMT devices and enhancement mode HEMT devices having different compositions of the AlₓSc₁₋ₓN alloy layer and co-integrated on the same integrated circuit die.

4. The method of claim 1, further including repeating the forming the AlGaN layer, the forming the AlₓSc₁₋ₓN alloy layer, and the forming the AlN layer, to form a vertically-stacked multi-channel HEMT device.

5. The method of claim 1, in which the forming the AlGaN buffer layer by deposition includes forming the AlGaN buffer layer by the low temperature CVD with concurrent PVD.

6. The method of claim 1, in which the forming the GaN body region layer by deposition includes forming the GaN body region layer by the low temperature CVD with concurrent PVD.

7. The method of claim 1, in which the low temperature CVD with concurrent PVD includes sputtering.

8. The method of claim 1, in which the low temperature CVD with concurrent PVD is performed in a chamber in which wafers are not arranged horizontally.

9. The method of any of claim 1, in which the low temperature CVD with concurrent PVD is performed in a chamber in which wafers are arranged vertically.

10. The method of claim 1, in which the AlₓSc₁₋ₓN alloy layer is formed with x less than 20%.

11. The method of claim 1, in which the AlₓSc₁₋ₓN alloy layer is formed with x between 5.5% and 12%.

12. A compound semiconductor integrated circuit including a high electron mobility transistor (HEMT), the integrated circuit including:
a body region that includes GaN and that is formed upon a substrate;
a source region;
a drain region;
a gate region;
a gate-source access region and a gate-drain access region;
an aluminum gallium nitride (AlGaN) layer on the body region;
an aluminum scandium nitride (AlₓSc₁₋ₓN) alloy layer on the AlGaN; and
an aluminum nitride (AlN) layer upon the AlₓSc₁₋ₓN alloy layer in at least the gate-drain access region of an enhancement mode HEMT device on the integrated circuit arranged such that electrons from the AlN layer contribute to a 2DEG in a channel region of body region of at least one of a gate-drain access region or a gate-source access region.

13. The integrated circuit of claim 12, in which the AlₓSc₁₋ₓN alloy layer includes different compositions of the AlₓSc₁₋ₓN alloy layer in the gate-source access region and the gate-drain access region.

14. The integrated circuit of claim 12, including a depletion mode HEMT and an enhancement mode HEMT co-integrated on the same integrated circuit die but having different compositions of the AlₓSc₁₋ₓN alloy layer therebetween.

15. The integrated circuit of claim 12, further including repeating the AlGaN layer, the AlₓSc₁₋ₓN alloy layer, and the AlN layer to form a vertically-stacked multi-channel HEMT device.

16. The integrated circuit of claim 12, in which at least one of the AlGaN layer, the AlₓSc₁₋ₓN alloy layer, and the AlN layer is a sputtered layer.

17. The integrated circuit of claim 12, in which the AlₓSc₁₋ₓN alloy layer includes a composition having x less than 20%.

18. The integrated circuit of claim 12, in which the AlₓSc₁₋ₓN alloy layer includes a composition having x between 5.5% and 12%.

19. A method of making a compound semiconductor high electron mobility transistor (HEMT), including a body region and further including a source region, a drain region, a gate region that define a gate-source access region and a gate-drain access region, the method comprising:
forming a gallium nitride (GaN) body region layer deposition upon a silicon or other substrate;
forming an aluminum gallium nitride (AlGaN) buffer layer by deposition upon the GaN body region layer;
forming an alloy layer including at least one of: (1) an aluminum scandium nitride (AlₓSc₁₋ₓN) alloy layer, or (2) an aluminum indium nitride (AlₓIn₁₋ₓN) alloy layer, the alloy layer formed on the AlGaN layer by low temperature chemical vapor deposition (CVD) at a first temperature of less than 400 degrees Celsius together with concurrent physical vapor deposition (PVD) at the same first temperature; and
using the low temperature CVD with the concurrent PVD, forming an aluminum nitride (AlN) layer upon alloy layer in at least the gate-drain access region of an enhancement mode HEMT device such that electrons from the AlN layer contribute to a 2DEG in a channel region of GaN body region of gate-drain access region.

20. The method of claim 19, in which the forming an alloy layer including at least one of: (1) an aluminum scandium nitride (AlₓSc₁₋ₓN) alloy layer, or (2) an aluminum indium nitride (AlₓIn₁₋ₓN) alloy layer, includes forming the aluminum scandium nitride (AlₓSc₁₋ₓN) alloy layer.

21. The method of claim 19, in which the forming an alloy layer including at least one of: (1) an aluminum scandium nitride (AlₓSc₁₋ₓN) alloy layer, or (2) an aluminum indium nitride (AlₓIn₁₋ₓN) alloy layer, includes forming the aluminum indium nitride (AlₓIn₁₋ₓN) alloy layer.

22. A compound semiconductor integrated circuit including a high electron mobility transistor (HEMT), the integrated circuit including:
a body region that includes GaN and that is formed upon a substrate;
a source region;
a drain region;
a gate region;
a gate-source access region and a gate-drain access region;
an aluminum gallium nitride (AlGaN) layer on the body region;
an alloy layer on the AlGaN layer, the alloy layer including at least one of: (1) an aluminum scandium nitride (AlₓSc₁₋ₓN) alloy layer on the AlGaN, or (2) an aluminum indium nitride (AlₓIn₁₋ₓN) alloy layer on the AlGaN; and
an aluminum nitride (AlN) layer upon the alloy layer in at least the gate-drain access region of an enhancement mode HEMT device on the integrated circuit arranged such that electrons from the AlN layer contribute to a 2DEG in a channel region of body region of gate-drain access region.

23. The integrated circuit of claim 22, in which the alloy layer includes the aluminum scandium nitride (AlₓSc₁₋ₓN) alloy layer.

24. The integrated circuit of claim 22, in which the alloy layer includes the aluminum indium nitride (AlₓIn₁₋ₓN) alloy layer.
